(19) United States
(12) Patent Application Publication
(10) Pub. No.: US 2005/0235918 A1
(43) Pub. Date: Oct. 27, 2005

(54) Substrate treating apparatus

(76) Inventors: Yasuhiko Kojima, Yamanashi (JP); Tadahiro Ishizaka, Yamanashi (JP); Yumiko Kawano, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/524,215

(22) PCT Filed: Aug. 20, 2003
(86) PCT No.: PCT/JP03/10506

§ 371 Date: Feb. 10, 2005

(30) Foreign Application Priority Data
Aug. 30, 2002 (JP) 2002-252267

(51) Int. Cl. C23C 16/00

(52) U.S. Cl. 118/733

(57) ABSTRACT

A substrate treating apparatus comprising a treatment chamber for housing a substrate, a stage on which the substrate is placed within the treatment chamber, a heating member arranged within the stage and used for heating the substrate, a sealing member arranged between the stage and the treatment chamber, and a cooling mechanism having a cooling medium, whose latent heat of vaporization is utilized for cooling the sealing member.

### FIELD OF THE INVENTION

The present invention relates to a substrate processing apparatus for processing a substrate while heating same.

### BACKGROUND OF THE INVENTION

There has been known in the art a film forming apparatus for forming a thin film on a semiconductor wafer (hereinafter simply refereed to as a “wafer”) by supplying a processing gas while heating the wafer. In case of such a film forming apparatus of this type, the wafer mounted on a susceptor is heated by flowing an electric current to a resistant heating element embedded in the susceptor.

In such a configuration, the resistance heating element and a power supply outside a chamber are connected to each other via lead lines; and in case the processing gas is brought in contact with the lead lines, there may be a likelihood that the lead lines are corroded by a chemical reaction between the lead lines and the processing gas. For the reason, a sealing member is installed between the chamber and the susceptor to prevent the contact between the lead lines and the processing gas.

Recently, there is a need for miniaturization of the film forming apparatus in terms of, e.g., consumption amount of the processing gas. However, if the film forming apparatus is miniaturized, the distance between the susceptor and the chamber is shortened, resulting in a problem that the sealing member cannot sustain heat and is melted.

### SUMMARY OF THE INVENTION

It is, therefore, an object of the present invention to provide a substrate processing apparatus capable of suppressing a rise of temperature of a sealing member.

In accordance with the present invention, there is provided a substrate processing apparatus including: a processing chamber for accommodating a substrate therein; a mounting table for mounting the substrate thereon; a heating member disposed in the mounting table, for heating the substrate; a sealing member disposed between the mounting table and the processing chamber; and a cooling unit, having a cooling medium, for cooling the sealing member by using a latent heat of vaporization of the cooling medium included therein. According to the substrate processing apparatus of the present invention, the sealing member can be cooled down by the cooling unit, so that a rise of temperature in the sealing member can be suppressed.

Further, the cooling unit includes a depressurized airtight casing for accommodating the cooling medium therein. By way of employing the airtight casing, the boiling point of the cooling medium can be reduced.

Preferably, the substrate processing apparatus further includes a temperature sensor disposed near the sealing member and a cooling unit controller for controlling the cooling unit based on a measurement result of the temperature sensor. By using the temperature sensor and the cooling unit controller, the temperature in the vicinity of the sealing member can be maintained at a desired level.

In accordance with the present invention, there is further provided a substrate processing apparatus including: a processing chamber for accommodating a substrate therein; a mounting table having a mounting portion for mounting thereon the substrate and having a support for supporting the mounting table; a heating member disposed in the mounting portion, for heating the substrate; a sealing member disposed between the support and the processing chamber; a shielding member for shielding a heat radiation directed toward the sealing member from the mounting table; and a shielding cap covering a bottom portion of the support.

Preferably, the shielding member covers at least a part of a bottom surface of the mounting portion. Here, the bottom surface of the mounting portion refers to a surface opposite to a surface of the mounting portion on which a substrate is loaded. By covering at least a part of the bottom surface of the mounting portion with the shielding cap, the heat radiation directed toward the sealing member from the mounting portion can be blocked successively.

Further, it is preferred that the substrate processing apparatus further includes a substrate elevating member for moving up and down the substrate and the shielding member supports the substrate elevating member. By the shielding member supporting the substrate elevating member, the number of parts involved can be reduced, resulting in a cost-down.

Preferably, the substrate processing apparatus further includes a processing gas supply system for supplying a processing gas into the processing chamber. In case the substrate processing apparatus is miniaturized, the consumption amount of the processing gas can be reduced.

The processing gas supply system includes a plurality of processing gas supply units for supplying different processing gases and a processing gas supply unit controller for controlling each of the processing gas supply units such that the processing gases are supplied alternately. In case the substrate processing apparatus is miniaturized, the time required to exhaust the processing gases can be reduced.

### BRIEF DESCRIPTION OF THE DRAWINGS

FIG. 1 is a schematic configuration view of a film forming apparatus in accordance with a first preferred embodiment of the present invention;

FIGS. 2A and 2B provide a schematic plan view and a schematic vertical cross sectional view of a wafer elevating pin support in accordance with the first embodiment of the present invention, respectively;

FIGS. 3A and 3B present a schematic plan view and a schematic vertical cross sectional view of a shielding cap in accordance with the first embodiment of the present invention, respectively;

FIG. 4 sets forth a schematic configuration view of a cooling unit in accordance with the first embodiment of the present invention;

FIG. 5 is a flowchart that describes a sequence of a processing method performed by the film forming apparatus in accordance with the first embodiment of the present invention;

FIGS. 6A to 6D are schematic drawings for describing the processing method performed by the film forming apparatus in accordance with the first preferred embodiment of the present invention;

FIG. 7 provides a schematic configuration view of a film forming apparatus in accordance with a second preferred embodiment of the present invention;

FIG. 8 offers a flowchart that describes a sequence of a processing method performed by the film forming apparatus in accordance with the second embodiment of the present invention;

FIGS. 9A and 9B depict a schematic plan view and a schematic vertical cross sectional view of a wafer elevating pin support in accordance with a third preferred embodiment of the present invention, respectively; and

FIGS. 10A and 10B present a schematic plan view and a schematic vertical cross sectional view of another wafer elevating pin support in accordance with the third embodiment of the present invention.

### DETAILED DESCRIPTION OF THE PREFERRED EMBODIMENTS

### First Preferred Embodiment

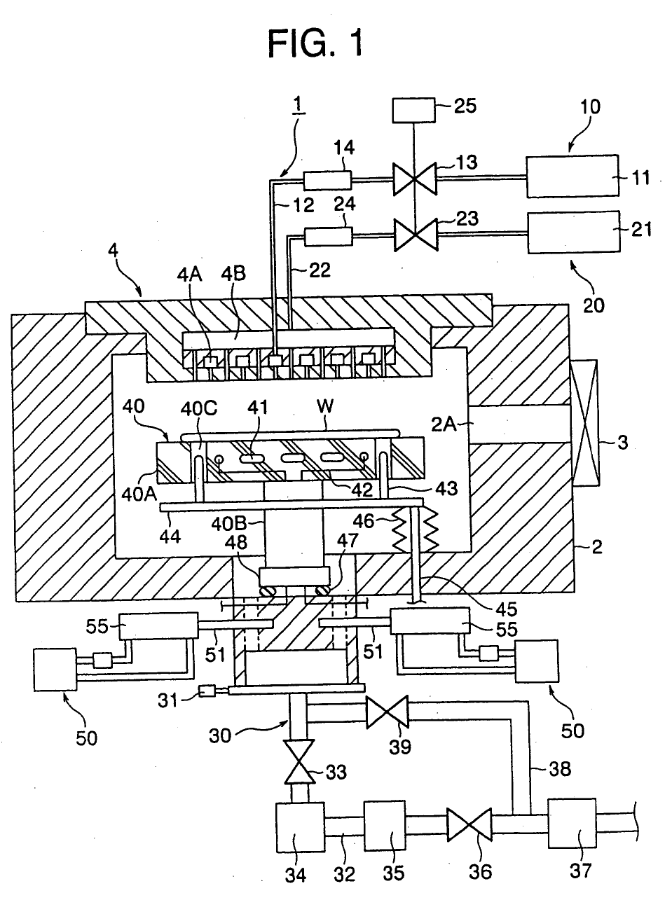

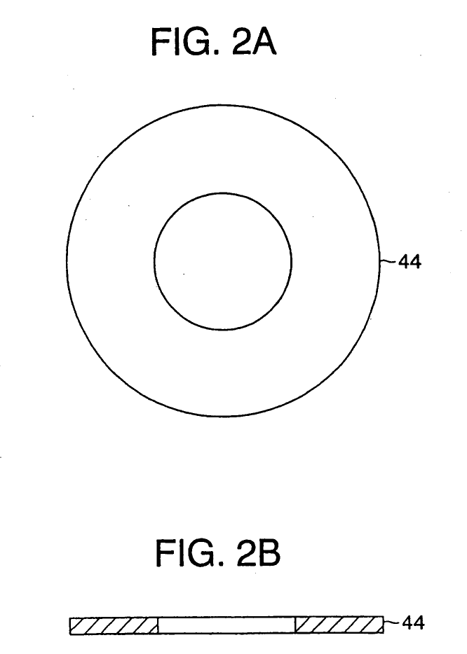

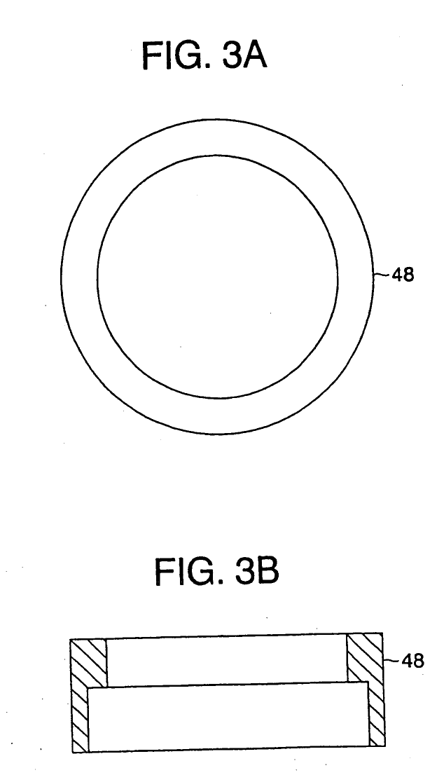

Hereinafter, a film forming apparatus in accordance with a first preferred embodiment of the present invention will be described. FIG. 1 is a schematic configuration view of the film forming apparatus and FIGS. 2A and 2B schematically show a plan view and a vertical cross sectional view of a wafer elevating pin support in accordance with the first embodiment, respectively. Further, FIGS. 3A and 3B schematically illustrate a plan view and a vertical cross sectional view of a shielding cap in accordance with the first embodiment, respectively.

As shown in FIG. 1, the film forming apparatus 1 includes a chamber 2 formed of, e.g., aluminum or stainless steel. Here, it may be preferred that the surface of the chamber 2 is, for example, alumite treated. An opening 2A is formed at a side portion of the chamber 2 and a gate valve 3 is installed near the opening 2A in order to allow a wafer W to be loaded into or unloaded from the chamber 2.

Further, an opening is formed at an upper portion of the chamber 2, and a shower head 4 for injecting TiCl₄ and NH₃ toward the wafer W is inserted into the opening. The shower head 4 includes a TiCl₄ injecting portion 4A for injecting TiCl₄ and a NH₃ injecting portion 4B for injecting NH₃. The TiCl₄ injecting portion 4A is provided with a number of TiCl₄ injection openings through which TiCl₄ is discharged. Likewise, the NH₃ injecting portion 4B has a multiplicity of NH₃ injection openings through which NH₃ is discharged.

Connected to the TiCl₄ injecting portion 4A of the shower head 4 is a TiCl₄ supply system 10 for supplying TiCl₄ thereto. And, connected to the NH₃ injecting portion 4B is a NH₃ supply system 20 for supplying NH₃ thereto.

The TiCl₄ supply system 10 includes a TiCl₄ supply source 11 containing therein TiCl₄. Connected to the TiCl₄ supply source 11 is a TiCl₄ supply line 12 whose one end is coupled to the TiCl₄ injecting portion 4A. Installed on the TiCl₄ supply line 12 are a valve 13 and a mass flow controller (MFC) 14 for controlling the flow rate of TiCl₄. By opening the valve 13 after setting the MFC 14, TiCl₄ is supplied into the TiCl₄ injecting portion 4A from the TiCl₄ supply source 11 at a predetermined flow rate.

The NH₃ supply system 20 includes a NH₃ supply source 21. Coupled to the NH₃ supply source 21 is a NH₃ supply line 22 whose one end is connected to the NH₃ injecting portion 4B. Installed on the NH₃ supply line are a valve 23 and a MFC 24 for controlling the flow rate of NH₃. By opening the valve 23 after setting the MFC 24, NH₃ is supplied into the NH₃ injecting portion 4B from the NH₃ supply source 21 at a preset flow rate.

Further, a valve controller 25 is electrically coupled to the valves 13 and 23 to control same to be opened alternately. By controlling the valves 13 and 23 in such a manner through the use of the valve controller 25, a TiN film having an excellent step coverage and the like can be formed on the wafer W.

Connected to the bottom portion of the chamber 2 is a gas exhaust system 30 for pumping out, e.g., TiCl₄ and NH₃ gases. The gas exhaust system 30 includes an automatic pressure controller (APC) 31 for controlling the internal pressure of the chamber 2. By controlling conductance with the APC 31, the internal pressure of the chamber 2 is controlled at a predetermined pressure level.

A gas exhaust line 32 is coupled to the APC 31. On the gas exhaust line 32, a main valve 33, a turbo molecular pump 34, a trap 35, a valve 36 and a dry pump 37 are installed in that order from the upstream side to the downstream side.

The turbo molecular pump 34 is for performing a main pumping process. By carrying out the main pumping through the use of the turbo molecular pump 34, the internal pressure of the chamber 2 is maintained at the predetermined pressure level. Furthermore, by way of evacuating the chamber 2 through the use of the turbo molecular pump 34, superfluous TiCl₄, NH₃, TiN, NH₄Cl and the like are exhausted from the chamber 2.

The trap 35 is for removing NH₄Cl from the exhaust gas by filtering out NH₄Cl contained in the exhaust gas. The dry pump 37 assists the turbo molecular pump 34. By operating the dry pump 37, the backing pressure of the turbo molecular pump 34 can be reduced. Furthermore, the dry pump 37 performs a rough pumping of the chamber 2.

Connected to the gas exhaust line 32 between the valve 36 and the dry pump 37 is a rough pumping line 38 for use in performing the rough pumping by means of the dry pump 37. The other end of the rough pumping line 38 is coupled to the gas exhaust line 32 between the APC 31 and the main valve 33. A valve 39 is installed on the rough pumping line 38. By operating the dry pump 37 under the condition that the main valve 33 and the valve 36 are closed while the valve 39 is opened, the chamber 2 is roughly evacuated.

A susceptor 40 is disposed in the chamber 2. The susceptor 40 includes an approximately disc-shaped mounting portion 40A for mounting thereon the wafer W and a support 40B for supporting the mounting portion 40A.

Disposed within the mounting portion 40A is a resistance heating element 41 which heats the mounting portion 40A to a predetermined temperature. Two lead lines 42, one end of each being connected to an external power supply (not shown), are coupled to the resistance heating element 41. By flowing an electric current to the resistance heating element 41 via the lead lines 42 from the external power supply, the mounting portion 40A is heated up to the predetermined temperature.

Holes 40C for use in moving up and down the wafer W are respectively formed in a vertical direction at three places in the mounting portion 40A, and a wafer elevating pin 43 is inserted into each of the holes 40C. The wafer elevating pins 43 are supported upright by a wafer elevating pin support 44.

The wafer elevating pin support 44 is formed as a ring-shaped flat plate, as shown in FIGS. 2A and 2B, and is installed between the mounting portion 40A and a sealing member 47 to be described later. The wafer elevating pin support 44 serves to support the wafer elevating pins 43 and also functions to shield a heat radiation directed toward the sealing member 47 from the mounting portion 40A.

The wafer elevating pin support 44 is formed of a material capable of effectively shielding a heat radiation. Specifically, the wafer elevating pin support 44 is formed of, e.g., any one of aluminum oxide, aluminum nitride, silicon carbide (SiC), quartz, stainless steel, aluminum, hastelloy, inconel and nickel.

An air cylinder (not shown) is fixed to the wafer elevating pin support 44. The air cylinder includes a rod 45. When the rod 45 is contracted by the operation of the air cylinder, the wafer elevating pins 43 are lowered and the wafer W is loaded on the mounting portion 40A. Further, when the rod 45 is extended by the operation of the air cylinder, the wafer elevating pins 43 are lifted, so that the wafer W is moved away from the mounting portion 40A. Further, an expansible/contractible bellows 46 is disposed inside the chamber 2 to cover the rod 45. By covering the rod 45 with the bellows 46, the inside of the chamber 2 can be maintained hermetically.

Inserted between the support 40B of the susceptor 40 and the chamber 2 is the ring-shaped sealing member 47 formed of a synthetic resin. By inserting the sealing member 47 therebetween, the lead lines 42 are prevented from contacting with TiCl₄, etc.

The bottom portion of the support 40B is covered with the shielding cap 48 which serves to shield the heat radiation directed toward the sealing member 47 from the mounting portion 40A. The shielding cap 48 has a hollow shape provided with an opening at a top surface thereof, as shown in FIGS. 3A and 3B.

The shielding cap 48 is formed of a material capable of effectively blocking a heat radiation. Specifically, the shielding cap 48 is formed of, e.g., any one of aluminum oxide, aluminum nitride, silicon carbide (SiC), quartz, stainless steel, aluminum, hastelloy, inconel and nickel.

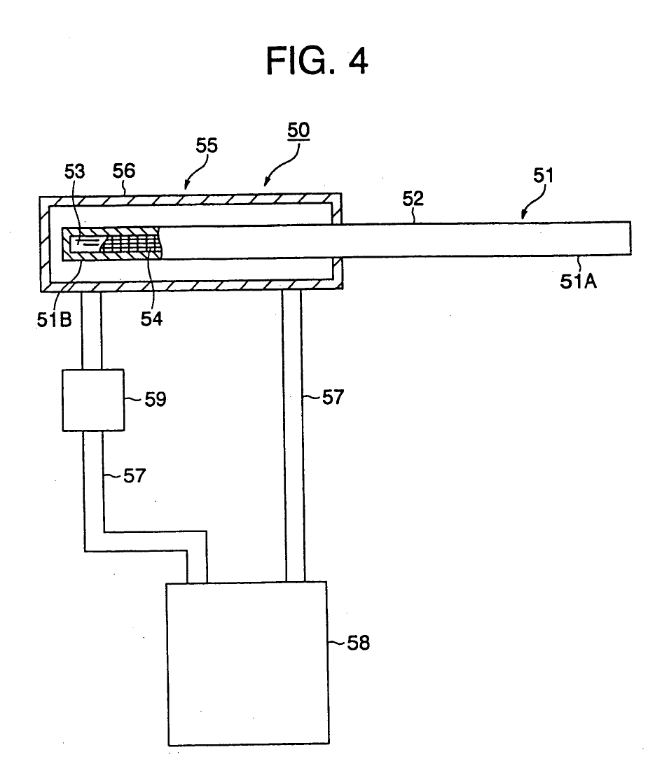

Openings are formed at two places of the bottom portion of the chamber 2, and a part of a cooling unit 50 for cooling the sealing member 47 is inserted into each of the openings. FIG. 4 shows a schematic configuration of the cooling unit 50 in accordance with the first embodiment of the present invention. As shown in FIG. 4, the cooling unit 50 includes a heat pipe 51 for cooling the sealing member 47, and an end portion 51A of the heat pipe 51 is inserted into the corresponding opening formed through the bottom portion of the chamber 2.

The heat pipe 51 has a cylindrical airtight casing 52, and a cooling medium 53 is accommodated in the airtight casing 52. For example, one of water, hydrofluoroether, alcohol such as ethanol, fluorine-contained inactive liquid and naphthalene can be used as the cooling medium 53. Moreover, a mixture of polyhydric alcohols, for example, a mixture of ethylene glycol and propylene glycol, can also be used as the cooling medium 53. By depressurizing the inside of the airtight casing 52, the boiling point of the cooling medium 53 is lowered compared with that under the atmospheric pressure.

Disposed in the airtight casing 52 is a wick 54 which serves to move the liquefied cooling medium 53 to the end portion 51A of the heat pipe 51 by a capillary force. The wick 54 has a shape of a wire net. The liquefied cooling medium 53 moved to the end portion 51A of the heat pipe 51 vaporizes by absorbing heat around the sealing member 47. The vaporized cooling medium 53 is then transferred to a base portion 51B of the heat pipe 51 and is cooled down by a condenser 55 to be described later, thereby being liquefied again. Then, the liquefied cooling medium 53 is transferred to the end portion 51A again by the wick 54. By repetition of this cycle, the sealing member 47 is cooled, so that a rise of temperature of the sealing member 27 is suppressed.

The condenser 55 is disposed outside the base portion 51B of the heat pipe 51 to cool the base portion, 51B, to thereby liquefy the vaporized cooling medium 53. The condenser 55 has a vessel 56 for enclosing the base portion 51B of the heat pipe 51. Further, a circulation line 57 for circulating the cooling medium 53 therethrough is connected to two places of the vessel 56, and a cooling medium supply source 58 for storing the cooling medium therein is connected to the circulation line 57. Further, installed on the circulation line 57 is a pump 59 for pumping the coolant medium from the cooling medium supply source 58. By the operation of the pump 59, the cooling medium circulates between the cooling medium supply source 58 and a space (cooling medium supply space) between the outer surface of the airtight casing 52 and the inner surface of the vessel 56 via the circulation line 57. Moreover, the pump 59 is configured to be able to control the flow rate of the cooling medium.

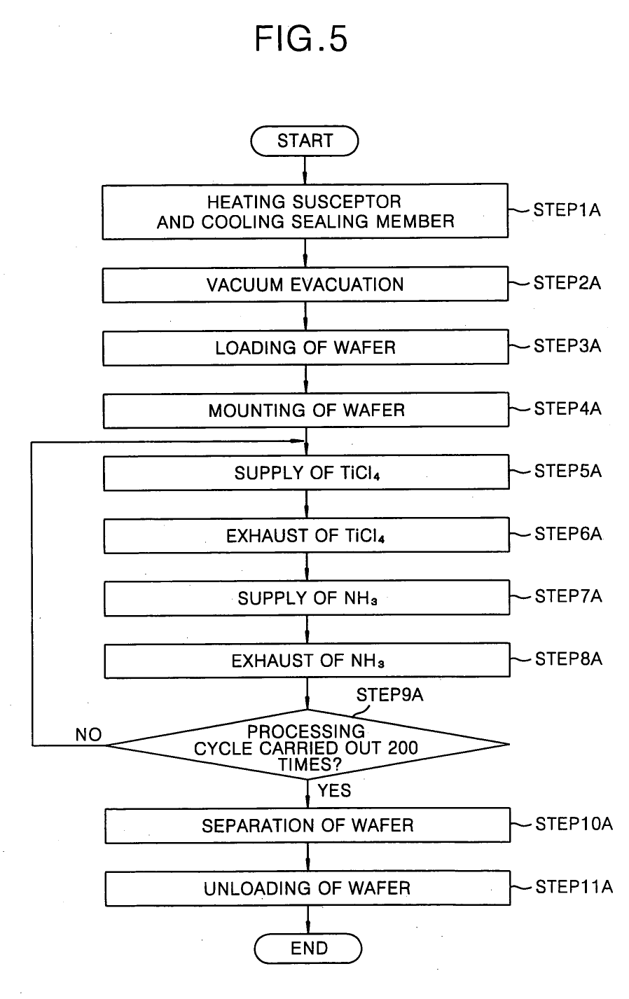

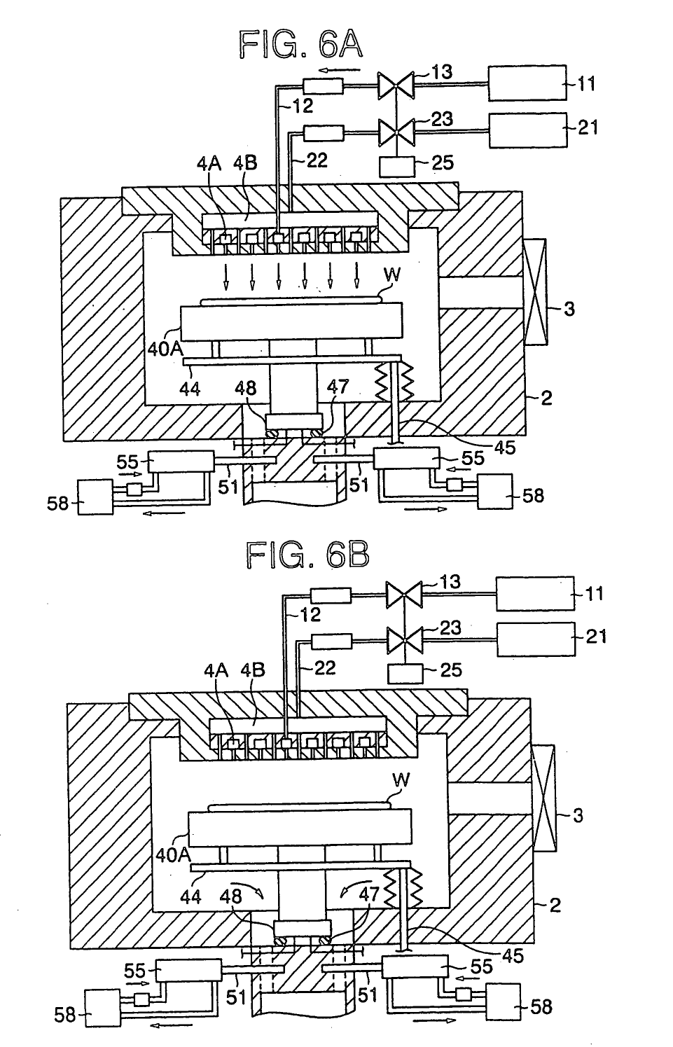

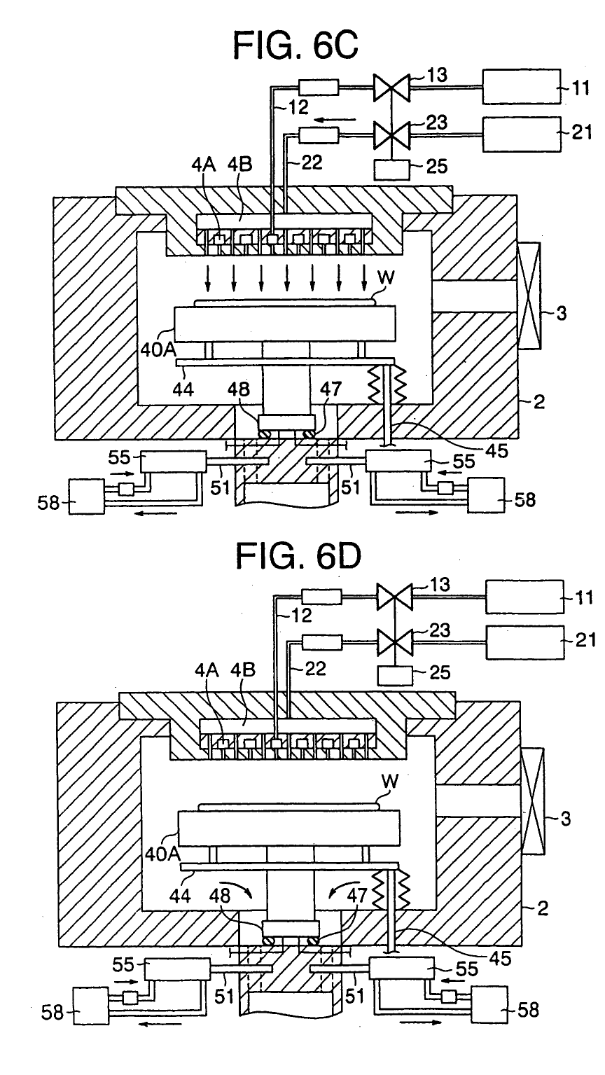

Hereinafter, a sequence of a processing method performed in the film forming apparatus 1 will be described with reference to FIGS. 5 and 6. FIG. 5 is a flowchart that describes the sequence of the processing method carried out by the film forming process 1 in accordance with the first embodiment and FIGS. 6A to 6D are schematic drawings describing the processing method performed by the film forming apparatus 1 in accordance with the first embodiment.

First, an electric current is supplied to the resistance heating element 41 disposed in the mounting portion 40A of the susceptor 40, so that the mounting portion 40A is heated up to about 300 to 450°. Further, a cooling medium is supplied into the cooling medium supply spaces, and the cooling of the sealing member 47 by the heat pipes 51 is started (Step 1A). The cooling medium is continuously circulated while the mounting portion 40A is heated.

Subsequently, the dry pump 37 is operated under the condition that the main valve 33 and the valve 36 are closed while the valve 39 is opened, to thereby perform a rough pumping of the chamber 2. Thereafter, when the internal pressure of the chamber 2 is reduced to a certain level, the valve 39 is closed and, at the same time, the main valve 33 and the valve 36 are opened. Then, the rough pumping by the dry pump 37 is switched to a main pumping by the turbo molecular pump 34 (Step 2A). Even after the switching to the main pumping, the dry pump 37 continues to operate.

When the internal pressure of the chamber 2 is reduced down to, for example, 1.33×10⁻² Pa or less, the gate valve 3 is opened and a transfer arm (not shown) on which a wafer W is supported is extended, so that the wafer W is loaded into the chamber 2 (Step 3A).

Thereafter, the transfer arm is contracted and the wafer W is placed on the wafer elevating pins 43. After the wafer is put on the wafer elevating pins 43, the wafer elevating pins 43 are lowered by the descent of the rod 45, to thereby load the wafer W on the mounting portion 40A which is heated to about 300 to 450° C. (Step 4A).

After the wafer W is loaded on the mounting portion 40A, the valve 13 is opened under the condition that the internal pressure of the chamber 2 is maintained at about 5 to 400 Pa, and TiCl₄ is injected toward the wafer W from the TiCl₄ injecting portion 4A at a flow rate of about 30 sccm, as shown in FIG. 6A (Step 5A). When the injected TiCl₄ comes in contact with the wafer W, TiCl₄ is adsorbed on the surface of the wafer W.

With the lapse of a predetermined time period, the valve 13 is closed, and the supply of TiCl₄ is stopped and TiCl₄ remaining in the chamber 2 is exhausted therefrom, as shown in FIG. 63 (Step 6A). When TiCl₄ is exhausted, the internal pressure of the chamber 2 is reduced to 6.67×10⁻² Pa or less.

After a predetermined time period has elapsed, the valve 23 is opened, and NH₃ is injected toward the wafer W from the NH₃ injecting portion 4B at a flow rate of about 100 sccm, as shown in FIG. 6C (Step 7A). When the injected NH₃ makes contact with TiCl₄ adsorbed on the wafer W, TiCl₄ and NH₃ react with each other to form a TiN film on the wafer W.

With the lapse of a predetermined time period, the valve 23 is closed, and the supply of NH₃ is stopped and NH₃, etc., remaining in the chamber 2 is exhausted therefrom, as shown in FIG. 6D (Step 8A). When NH₃ is exhausted, the internal pressure of the chamber 2 is reduced to about 6.67×10⁻² Pa or less.

Then, with the lapse of another predetermined time period, it is determined by a central controller (not shown) whether a processing cycle from the steps 5A to 8A has been repeated 200 times (Step 9A). If it is determined that the processing cycle has not been performed 200 times yet, the steps 5A to 8A are performed again.

If it is determined that the processing cycle has been repeated 200 times, the wafer elevating pins 43 are lifted by the ascent of the rod 45, so that the wafer W is separated from the mounting portion 40A (Step 10A). Upon completion of the 200 times repetition of the processing cycle, a TiN film with a thickness of about 10 nm is deposited on the wafer W.

Thereafter, the gate valve 3 is opened, and the transfer arm (not shown) is extended to receive the wafer W thereon. Then, the transfer arm is contracted, so that the wafer W is unloaded from the chamber 2 (Step 11A).

In this embodiment, since the heat pipes 51 are provided, the sealing member 47 can be cooled to suppress a rise in the temperature thereof. As a result, the sealing member 47 can be protected from being melted even in a case where the film forming apparatus 1 is reduced in size.

Further, if a miniaturized film forming apparatus 1 is employed in case of supplying TiCl₄ and NH₃ alternately as in this preferred embodiment, less amounts of TiCl₄ and NH₃ are consumed; and the amounts of TiCl₄ and NH₃ supplied into the chamber 2 are reduced as well, which gives rise to an effect of reducing the time period required to exhaust TiCl₄ and NH₃.

Japanese Patent Laid-open Publication No. H4-78138 discloses a technical scheme for cooling parts of a chamber by using of a water cooling jacket installed in the chamber. Here, the water cooling jacket performs a cooling operation by way of circulating a cooling medium. In contrast, the heat pipe 51 carries out a cooling operation by using latent heat of vaporization, and provides a higher cooling power than that of the water cooling jacket. Furthermore, in case of using the water cooling jacket, air bubbles may be generated in a tube as water therein vaporizes, resulting in the expansion of the tube. However, in the case of using the heat pipes 51, the expansion of the airtight casing 52 can be avoided even with the vaporization of the cooling medium 53 taking place at the end portion of the heat pipe 51, because the cooling medium 53 is liquefied at the base portion 51B.

Further, in accordance with the first embodiment described above, since the wafer elevating pin support 44 and the shielding cap 48 are disposed between the mounting portion 40A and the sealing member 47, a heat radiation directed toward the sealing member 47 from the mounting portion 40A can be reduced, thereby suppressing a temperature rise of the sealing member 47.

### Second Preferred Embodiment

A second preferred embodiment of the present invention will now be described. Further, in preferred embodiments to be described hereinafter, descriptions identical to those in a preceding embodiment may be omitted. The second embodiment is directed to a scheme for measuring the temperature in the vicinity of a sealing member by using a temperature sensor and controlling the cooling power of a heat pipe based on a measurement result provided from the temperature sensor.

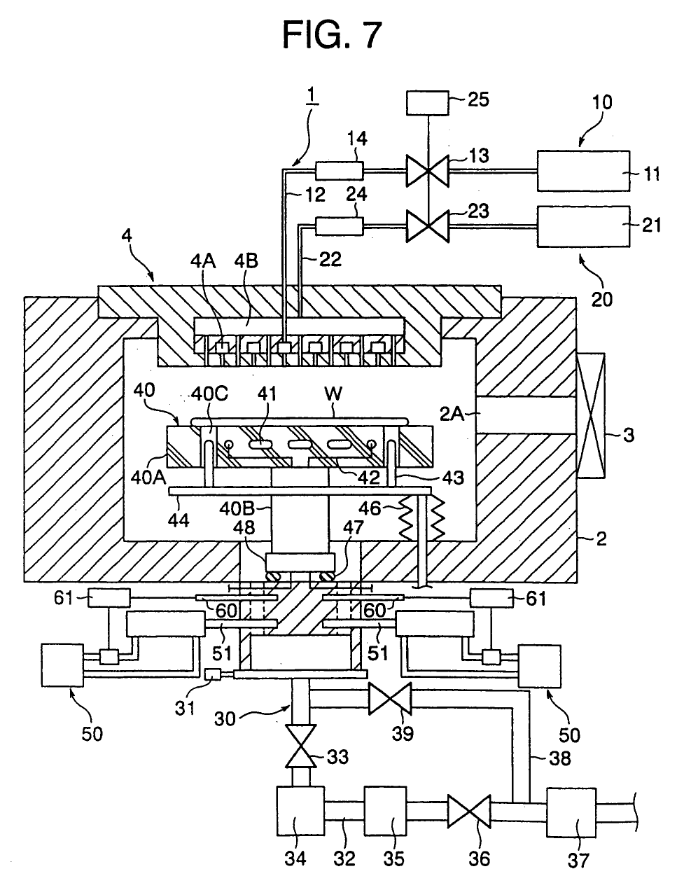

FIG. 7 shows a schematic configuration of a film forming apparatus in accordance with the second embodiment of the present invention. As shown in FIG. 7, openings are formed in the bottom portion of a chamber 2 near a sealing member 47, and temperature sensors 60 are inserted into the respective openings. Further, electrically connected to the temperature sensors 60 are cooling unit controllers 61, which are in turn coupled to the pumps 59.

The cooling unit controllers 61 control flow rates of the cooling medium which flows in cooling medium supply spaces to control cooling powers of the heat pipes 51. Specifically, the cooling unit controllers 61 compare the measurement results from the temperature sensors 60 with a preset temperature stored in the cooling unit controllers 61, and, based on the comparison results, control (feedback control) the operation of the pumps 59 such that the temperature in the vicinity of the sealing member 47 is maintained at the preset level. Here, if the flow rates of the cooling medium supplied into the cooling medium supply spaces are increased, the base portions 51B of the heat pipes 51 are further cooled down, resulting in an increased cooling powers of the heat pipes 51.

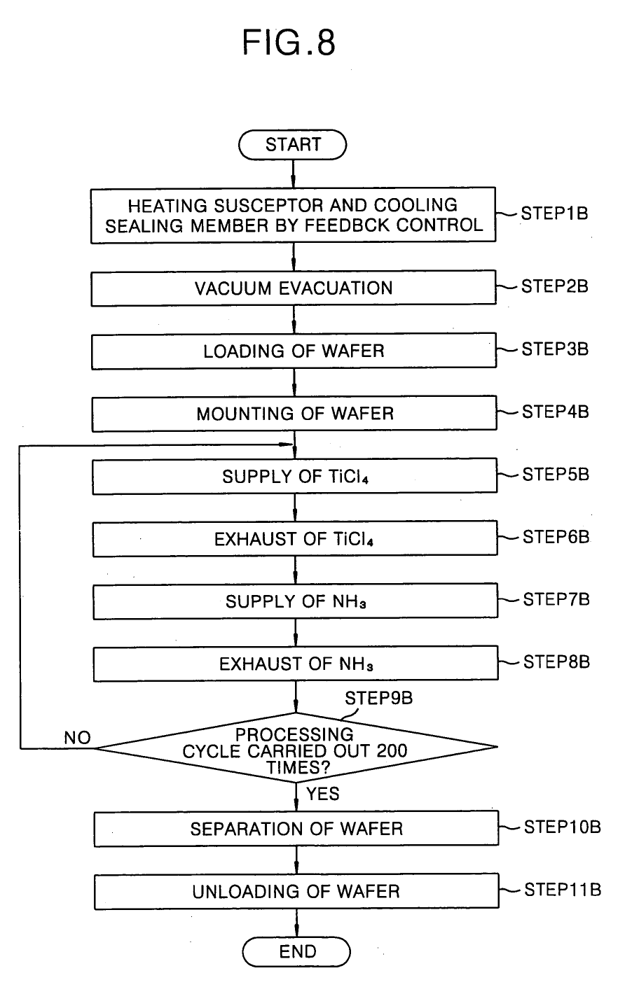

Hereinafter, a sequence of a processing method performed by the film forming apparatus 1 will be described with reference to FIG. 8. FIG. 8 presents a flowchart showing the sequence of the processing method executed by the film forming apparatus 1 in accordance with the second embodiment.

First, an electric current is supplied to the resistance heating element 41, and the mounting portion 40A is heated up to about 300 to 450°. Further, the temperatures near the sealing member 47 are measured by the temperature sensors 60, and cooling of the sealing member 47 by the heat pipes 51 is executed while controlling the flow rates of the cooling medium supplied into the cooling medium supply spaces based on the measurement results (Step 1B). Further, the temperature measurement by the temperature sensors 60 and the control of the flow rates of the cooling medium based on the measurement results of the temperature sensors 60 are performed every predetermined time interval while the mounting portion 40A is being heated.

Subsequently, the dry pump 37 is operated to thereby perform a rough pumping of the chamber 2. Thereafter, the rough pumping by the dry pump 37 is switched to a main pumping by the turbo molecular pump 34 (Step 2B).

When the internal pressure of the chamber 2 is reduced down to, for example, 1.33×10⁻² Pa or less, the transfer arm (not shown) on which a wafer W is placed is extended, so that the wafer W is loaded into the chamber 2 (Step 3B). Then, wafer elevating pins 43 are lowered, to thereby load the wafer W on the mounting portion 40A (Step 4B).

After the wafer W is loaded on the mounting portion 40A, the valve 13 is opened under the condition that the internal pressure of the chamber 2 is maintained at about 5 to 400 Pa, and TiCl₄ is injected toward the wafer W from the TiCl₄ injecting portion 4A (Step 5B). Then, with the lapse of a predetermined time period, the valve 13 is closed, and the supply of TiCl₄ is stopped and TiCl₄ remaining in the chamber 2 is exhausted therefrom (Step 6B).

After a preset time period has elapsed, the valve 23 is opened, and NH₃ is injected toward the wafer W from the NH₃ injecting portion 4B (Step 7B), and, with the lapse of another preset time period, the valve 23 is closed, and the supply of NH₃ is stopped and NH₃, etc., remaining in the chamber 2 is exhausted therefrom (Step 8B).

Then, after a predetermined time period, it is determined whether a processing cycle from the steps 5B to 8B has been repeated 200 times (Step 9B). If it is determined that the cycle has not been executed 200 times yet, the processes of steps S5 to 8B are performed again.

If it is determined that the processing cycle has been repeated 200 times, the wafer elevating pins 43 are lifted, so that the wafer W is separated from the mounting portion 40A (Step 10B). Finally, the wafer W is unloaded from the chamber 2 by the transfer arm (not shown) (Step 11B).

In the second embodiment, the temperatures near the sealing member 47 are measured by the temperature sensors 60 and the cooling powers of the heat pipes 51 are controlled based on the measurement results of the temperature sensors 60, thereby making it possible to maintain the vicinity of the sealing member 47 at a desired temperature.

### Third Preferred Embodiment

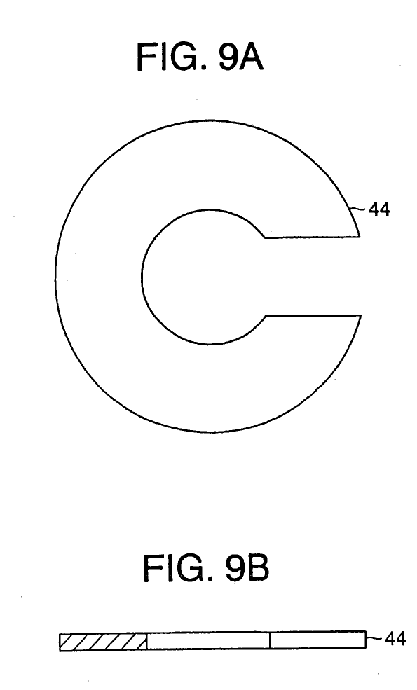

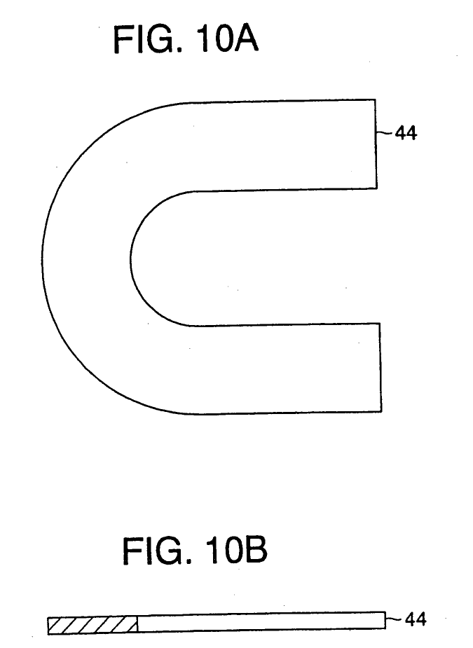

Hereinafter, a third preferred embodiment of the present invention will be described, in which variations of the shape of a wafer elevating pin support are illustrated. FIGS. 9A and 9B schematically show a plan view and a vertical cross sectional view of a wafer elevating pin support in accordance with the third embodiment, respectively. FIGS. 10A and 10B schematically illustrate a plan view and a vertical cross sectional view of a modification of the wafer elevating pin support in accordance with the third embodiment, respectively.

As shown in FIGS. 9A and 9B, a wafer elevating pin support 44 is formed as a ring-shaped plate, wherein a part thereof is cut out. Further, the wafer elevating pin support 44 may be formed as a U-shaped plate, as shown in FIGS. 10A and 10B. Even with the wafer elevating pin supports 44 of such shapes, same effects as in the first and the second embodiment can be obtained.

Moreover, the present invention is not limited to the preferred embodiments described above and various modifications of, e.g., structures, materials and arrangements of the components can be made without departing from the spirit and scope of the present invention. Though the first and the second embodiment have been described to include the wafer elevating pin support 44 and the shielding cap 48, they may be omitted in case a cooling unit 50 is installed. Further, conversely, in case the wafer elevating pin support 44 and the shielding cap 48 are installed, the cooling unit 50 may be omitted. Furthermore, though both the wafer elevating pin support 44 and the shielding cap 48 are disposed between the mounting portion 40A and the sealing member 47, it may also be sufficient to install either one of them.

Further, though a cooling unit for cooling the wafer elevating pin support 44 is not installed thereon in the first and the second embodiment, it is also possible to install the cooling unit on the wafer elevating pin support 44. Likewise, the cooling unit may also be installed on the shielding cap 48.

Table 1 shows types of films and processing gases employed to form such films. Though the first and the second embodiment have been described for the case of using TiCl₄ and NH₃, other processing gases shown in FIG. 1 can be used as well.

TABLE 1

| Types | First | Second | Third |
|---|---|---|---|
| Of | Processing | Processing | Processing |
| Film | Gas | Gas | Gas |
| TiN | TiCl₄ | NH₃ | — |
| | TiF₄ | NH₃ | — |
| | TiBr₄ | NH₃ | — |
| | TiI₄ | NH₃ | — |
| | TEMAT | NH₃ | — |
| | TDMAT | NH₃ | — |
| | TDEAT | NH₃ | — |
| TiSiN | TiCl₄ | NH₃ | SiH₄ |
| | TiF₄ | NH₃ | SiH₄ |
| | TiBr₄ | NH₃ | SiH₄ |
| | TiI₄ | NH₃ | SiH₄ |
| | TEMAT | NH₃ | SiH₄ |
| | TDMAT | NH₃ | SiH₄ |
| | TDEAT | NH₃ | SiH₄ |
| | TiCl₄ | NH₃ | Si₂H₆ |
| | TiF₄ | NH₃ | Si₂H₆ |
| | TiBr₄ | NH₃ | Si₂H₆ |
| | TiI₄ | NH₃ | Si₂H₆ |
| | TEMAT | NH₃ | Si₂H₆ |
| | TDMAT | NH₃ | Si₂H₆ |
| | TDEAT | NH₃ | Si₂H₆ |
| | TiCl₄ | NH₃ | SiH₂Cl₂ |
| | TiF₄ | NH₃ | SiH₂Cl₂ |
| | TiBr₄ | NH₃ | SiH₂Cl₂ |
| | TiI₄ | NH₃ | SiH₂Cl₂ |
| | TEMAT | NH₃ | SiH₃Cl₂ |
| | TDMAT | NH₃ | SiH₂Cl₂ |
| | TDEAT | NH₃ | SiH₂Cl₂ |
| | TiCl₄ | NH₃ | SiCl₄ |
| | TiF₄ | NH₃ | SiCl₄ |
| | TiBr₄ | NH₃ | SiCl₄ |
| | TiI₄ | NH₃ | SiCl₄ |
| | TEMAT | NH₃ | SiCl₄ |
| | TDMAT | NH₃ | SiCl₄ |
| | TDEAT | NH₃ | SiCl₄ |
| TaN | TaF₅ | NH₃ | — |
| | TaCl₅ | NH₃ | — |
| | TaBr₅ | NH₃ | — |
| | TaI₅ | NH₃ | — |
| | TBTDET | NH₃ | — |
| TaSiN | TaF₅ | NH₃ | SiH₄ |
| | TaCl₅ | NH₃ | SiH₄ |
| | TaBr₅ | NH₃ | SiH₄ |
| | TaI₅ | NH₃ | SiH₄ |
| | TBTDET | NH₃ | SiH₄ |
| | TaF₅ | NH₃ | Si₂H₆ |
| | TaCl₅ | NH₃ | Si₂H₆ |
| | TaBr₅ | NH₃ | Si₂H₆ |
| | TaI₅ | NH₃ | Si₂H₆ |
| | TBTDET | NH₃ | Si₂H₆ |
| | TaF₅ | NH₃ | SiH₂Cl₂ |
| | TaCl₅ | NH₃ | SiH₂Cl₂ |
| | TaBr₅ | NH₃ | SiH₂Cl₂ |
| | TaI₅ | NH₃ | SiH₂Cl₂ |
| | TBTDET | NH₃ | SiH₂Cl₂ |
| | TaF₅ | NH₃ | SiCl₄ |
| | TaCl₅ | NH₃ | SiCl₄ |
| | TaBr₅ | NH₃ | SiCl₄ |
| | TaI₅ | NH₃ | SiCl₄ |
| | TBTDET | NH₃ | SiCl₄ |
| Al₂O₃ | Al (CH₃)₃ | H₂O | |
| | Al (CH₃)₃ | H₂O₂ | |
| ZrO₂ | Zr (O-t(C₄H₉) )₄ | H₂O | |
| | Zr (O-t(C₄H₉) )₄ | H₂O₃ | |
| | ZrCl₄ | H₂O | |
| | ZrCl₄ | H₂O₂ | |
| Ta₂O₅ | Ta (OC₂H₅)₅ | O₂ | |
| | Ta (OC₂H₅)₅ | H₂O | |
| | Ta (OC₂H₅)₅ | H₂O₂ | |

Though the mounting portion 40A is heated to about 300 to 450° C. in the first and the second embodiment, it should be apparent that the heating temperature may be changed depending on the processing gas involved. For example, the mounting portion 40A is heated up to about 300 to 450° C. when TaF₅+NH₃, TaCl₅+NH₃, TiCl₄+SiH₂Cl₂+NH₃, TiCl₄+SiH₄+NH₃ or TiCl₄+SiCl₄+NH₃ shown in Table 1 is used. On the other hand, the mounting portion 40A is heated up to about 150 to 500° C. when Al(CH₃₎₃+H₂O, or Al(CH₃)₃+H₂O₂ is employed. Further, in case of using Zr(O-t(C₄H₉))₄+H₂O or Zr(O-t(C₄H₉))₄+H₂O₂, the mounting portion 40A is heated up to 150 to 300° C. Still further, when Ta(OC₂H₅)₅+O₂, Ta(OC₂H₅)₅+H₂O or Ta(OC₂H₅)₅+H₂O₂ is used, the mounting portion 40A is heated up to about 150 to 600° C.

Moreover, though the film forming process is performed by supplying TiCl₄ and NH₃ alternately in the first and the second embodiment, it is also possible to execute the film forming process by supplying them simultaneously. Further, a glass substrate can be used instead of the wafer W.

Though the first and the second embodiment have been described in connection with to the film forming apparatus 1, the present invention can be applied to any apparatuses that performs a processing on a substrate while heating the substrate. Specifically, for example, the present invention can be applied to an etching apparatus, a sputtering apparatus, a vacuum evaporation apparatus, etc. In addition, in case of using two or more etching gases, the etching gases can be supplied either alternately or simultaneously.

### INDUSTRIAL APPLICABILITY

The substrate processing apparatus in accordance with the present invention can be employed in the field of manufacturing semiconductors.

While the invention has been shown and described with respect to the preferred embodiments, it will be understood by those skilled in the art that various changes and modifications may be made without departing from the spirit and scope of the invention as defined in the following claims.

1. A substrate processing apparatus comprising:
a processing chamber for accommodating a substrate therein;
a mounting table for mounting the substrate thereon;
a heating member disposed in the mounting table, for heating the substrate;
a sealing member disposed between the mounting table and the processing chamber; and
a cooling unit, having a cooling medium, for cooling the sealing member by using a latent heat of vaporization of the cooling medium included therein.

2. The apparatus of claim 1, wherein the cooling unit includes a depressurized airtight casing for accommodating the cooling medium therein.

3. The apparatus of claim 1, further comprising a temperature sensor disposed near the sealing member and a cooling unit controller for controlling the cooling unit based on a measurement result of the temperature sensor.

4. The apparatus of claim 1, further comprising a processing gas supply system for supplying a processing gas into the processing chamber.

5. The apparatus of claim 4, wherein the processing gas supply system includes a plurality of processing gas supply units for supplying different processing gases and a processing gas supply unit controller for controlling each of the processing gas supply units such that the processing gases are supplied alternately.

6. A substrate processing apparatus comprising:
a processing chamber for accommodating a substrate therein;
a mounting table having a mounting portion for mounting thereon the substrate and a support for supporting the mounting portion;
a heating member disposed in the mounting portion, for heating the substrate;
a sealing member disposed between the support and the processing chamber;
a shielding member for shielding a heat radiation directed toward the sealing member from the mounting portion; and
a shielding cap covering a bottom portion of the support.

7. The apparatus of claim 6, wherein the shielding member covers at least a part of a bottom surface of the mounting portion.

8. The apparatus of claim 6, further comprising a substrate elevating member for elevating the substrate, wherein the shielding member supports the substrate elevating member.

9. The apparatus of claim 6, further comprising a processing gas supply system for supplying a processing gas into the processing chamber.

10. The apparatus of claim 9, wherein the processing gas supply system includes a plurality of processing gas supply units for supplying different processing gases and a processing gas supply unit controller for controlling each of the processing gas supply units such that the processing gases are supplied alternately.
